(19) United States
(12) Patent Application Publication
(10) Pub. No.: US 2024/0215386 A1
(43) Pub. Date: Jun. 27, 2024

(54) OLED DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventors: Gang FANG, Wuhan (CN); Wenbing ZHANG, Wuhan (CN); Feng GAO, Wuhan (CN); Baoyou WANG, Wuhan (CN); Ce CHEN, Wuhan (CN)

(21) Appl. No.: 18/474,700

(22) Filed: Sep. 26, 2023

(30) Foreign Application Priority Data
Dec. 22, 2022 (CN) 202211657336.6

(51) Int. Cl. H10K 59/84

(52) U.S. Cl. CPC H10K 59/84

(57) ABSTRACT

An Organic light emitting diode (OLED) display device includes an anode, a cathode correspondingly disposed to the anode, and a plurality of OLED modules, disposed in series between the anode and the cathode. One of the plurality of OLED modules includes a plurality of OLED display units connected in parallel.

### CROSS REFERENCE TO RELATED APPLICATION

This application claims priority to Chinese Application No. 202211657336.6, filed on Dec. 22, 2022. The entire disclosure of the above application is incorporated herein by reference.

### FIELD OF THE INVENTION

The present disclosure relates to the field of display, more particularly, to an OLED display device.

### BACKGROUND

An Organic Light-Emitting Diode (OLED) display device has many advantages such as self-illumination, low driving voltage, high luminous efficiency, short response time, wide operating temperature range, and flexible display, and is recognized by the industry as the most promising display device.

However, the existing OLED devices have the problem of short service life, which limits the application scope of OLED display technology and reduces the market competitiveness of OLED display products.

### SUMMARY

The embodiment of the present disclosure provides an OLED display device with high luminous brightness and long service life. The OLED display device has a wide range of applications, not only suitable for small size display products such as mobile phones, but also suitable for notebooks, tablet computers and other medium-sized display products, and can enhance the market competitiveness of OLED display products.

An embodiment of the present disclosure provides an OLED display device. The OLED display device includes an anode, a cathode correspondingly disposed to the anode, and a plurality of OLED modules, disposed in series between the anode and the cathode. One of the plurality of OLED modules includes a plurality of OLED display units connected in parallel.

In some embodiments of the present disclosure, the plurality of OLED display units connected in parallel are controlled individually by independent switches.

In some embodiments of the present disclosure, at least one of the plurality of OLED modules is a single OLED display unit.

In some embodiments of the present disclosure, the OLED display unit includes a hole injection layer, a hole transport layer, a light-emitting layer, an electron transport layer, and an electron injection layer laminated in succession in a direction from the anode to the cathode.

In some embodiments of the present disclosure, there is a charge connection layer disposed between any two adjacent OLED modules of the plurality of OLED modules.

In some embodiments of the present disclosure, the charge connection layer includes an N-type doping material layer and a P-type doping material layer disposed in layers.

In some embodiments of the present disclosure, the N-type doping material layer includes an N-type dopant and a first host material that is an organic material, and the P-type doping material layer includes a P-type dopant and a second host material that is an organic material.

In some embodiments of the present disclosure, the first host material and a material of the electron transport layer are identical, or the first host material and a material of the electron injection layer are identical. The second host material and a material of the hole transport layer are identical, or the second host material and a material of the hole injection layer are identical.

In some embodiments of the present disclosure, the P-type dopant is selected from TCNQ, WO₃, ReO₃ and MoO₃, and the N-type dopant is selected from Li, Cs, Yb, Cs₂CO₃, Li₂CO₃, and Li₃N.

In some embodiments of the present disclosure, the plurality of OLED modules include a first OLED module, a second OLED module, and a third OLED module set sequentially in a direction from the anode to the cathode. The OLED display device further includes a first charge connection layer connected between the first OLED module and the second OLED module, and a second charge connection layer connected between the second OLED module and the third OLED module. Each of the first OLED module and the third OLED module is composed of a single OLED display unit, and the second OLED module is composed of a plurality of OLED display units connected in parallel.

In some embodiments of the present disclosure, the plurality of OLED modules include a fourth OLED module and a fifth OLED module disposed sequentially in a direction from the anode to the cathode. The OLED display device further includes a third charge connection layer, between the fourth OLED module and the fifth OLED module. The fourth OLED module is composed of a single OLED display unit, and the fifth OLED module is composed of a plurality of OLED display units connected in parallel.

In some embodiments of the present disclosure, the plurality of OLED modules include a sixth OLED module, a seventh OLED module, and an eighth OLED module disposed sequentially in the direction from the anode to the cathode. The OLED display device further includes a fourth charge connection layer connected between the sixth OLED module and the seventh OLED module, and a fifth charge connection layer, connected between the seventh OLED module and the eighth OLED module. Each of sixth OLED module and the eighth OLED module is composed of a plurality of OLED display units connected in parallel, and the seventh OLED module is composed of a single OLED display unit.

Another embodiment of the present disclosure provides an OLED display device. The OLED display device includes an anode, a cathode, a plurality of OLED modules, disposed between the anode and the cathode. One of the plurality of OLED modules includes a plurality of OLED display units connected in parallel, and the plurality of OLED display units are controlled individually to adjust a luminous brightness of the OLED display device.

In some embodiments of the present disclosure, the plurality of OLED display units connected in parallel are controlled individually by independent switches.

In some embodiments of the present disclosure, at least one of the plurality of OLED modules is a single OLED display unit.

In some embodiments of the present disclosure, the OLED display unit includes a hole injection layer, a hole transport layer, a light-emitting layer, an electron transport layer, and an electron injection layer laminated in succession in a direction from the anode to the cathode.

In some embodiments of the present disclosure, there is a charge connection layer disposed between any two adjacent OLED modules of the plurality of OLED modules.

In some embodiments of the present disclosure, the charge connection layer includes an N-type doping material layer and a P-type doping material layer disposed in layers.

In some embodiments of the present disclosure, the N-type doping material layer includes an N-type dopant and a first host material that is an organic material, and the P-type doping material layer includes a P-type dopant and a second host material that is an organic material.

In some embodiments of the present disclosure, the first host material and a material of the electron transport layer are identical, or the first host material and a material of the electron injection layer are identical. The second host material and a material of the hole transport layer are identical, or the second host material and a material of the hole injection layer are identical.

According to of embodiments of the present disclosure, the OLED display device utilizes a plurality of OLED modules connected in series, and at least one OLED module having a plurality of OLED display units connected in parallel. The OLED display device is provided with a plurality of OLED display units connected in series between the cathode and the anode. In contrast to a conventional OLED display device, the OLED display device can produce a larger luminous brightness under a smaller driving current. That is, under the same driving current, the luminous brightness of the OLED display device of the present disclosure is greater than the luminous brightness of the conventional OLED display device. Therefore, when the luminous brightness of the OLED display device of the present disclosure is controlled to be the same as the luminous brightness of the traditional OLED display device, based on the same aging mechanism, the OLED display device embodiment of the present disclosure can obtain a longer service life than the traditional OLED display device Due to its high luminous brightness and long service life, the OLED display device embodiment of the present disclosure has a wide range of applications, not only suitable for small size display products such as mobile phones, but also suitable for notebooks, tablet computers and other medium-sized display products, and can enhance the market competitiveness of OLED display products.

### BRIEF DESCRIPTION OF THE DRAWINGS

In order to more clearly illustrate the technical solution in the embodiment of the present disclosure, the following will be a brief introduction to the drawings required in the description of the embodiment. Obviously, the drawings described below are only some embodiments of the present disclosure, for those skilled in the art, without the premise of creative labor, may also obtain other drawings according to these drawings.

FIG. 1 is a schematic diagram of an OLED display device according to a first embodiment of the present disclosure.

FIG. 2 is a schematic diagram of an OLED display unit according to an embodiment of the present disclosure.

FIG. 3 is a schematic diagram of the structure of an OLED module according to an embodiment of the present disclosure.

FIG. 4 is a schematic diagram of an OLED display device according to a second embodiment of the present disclosure.

FIG. 5 is a schematic diagram of an OLED display device according to a third embodiment of the present disclosure.

### DETAILED DESCRIPTION OF PREFERRED EMBODIMENTS

To help a person skilled in the art better understand the solutions of the present disclosure, the following clearly and completely describes the technical solutions in the embodiments of the present invention with reference to the accompanying drawings in the embodiments of the present invention. Apparently, the described embodiments are a part rather than all of the embodiments of the present invention. All other embodiments obtained by a person of ordinary skill in the art based on the embodiments of the present invention without creative efforts shall fall within the protection scope of the present disclosure.

The term “first”, “second” are for illustrative purposes only and are not to be construed as indicating or imposing a relative importance or implicitly indicating the number of technical features indicated. Thus, a feature that limited by “first”, “second” may expressly or implicitly include at least one of the features.

In the description of the present disclosure, the meaning of “plural” is two or more, unless otherwise specifically defined.

Throughout the specification and claims, when it is described that an element is “connected” to another element, the element may be “directly connected” to the other element, or “electrically connected” to the other element through a third element.

Furthermore, the term “comprising” will be understood as meaning the inclusion of elements but not the exclusion of any other elements, unless explicitly described to the contrary.

The following disclosure provides many different embodiments or examples to implement different structures of the present disclosure. In order to simplify the disclosure of the present disclosure, the components and settings of specific examples are described below. They are for example purposes only and are not intended to limit this application. Further, the present disclosure may repeat reference numbers and/or reference letters in different examples, such duplication is for the purpose of simplification and clarity, and does not by itself indicate the relationship between the various embodiments and/or settings discussed. Further, the present disclosure provides various examples of specific processes and materials, but those of ordinary skill in the art may be aware of the application of other processes and/or the use of other materials. The following are described in detail, it should be noted that the order of description of the following embodiments is not used as a qualification for the preferred order of embodiments.

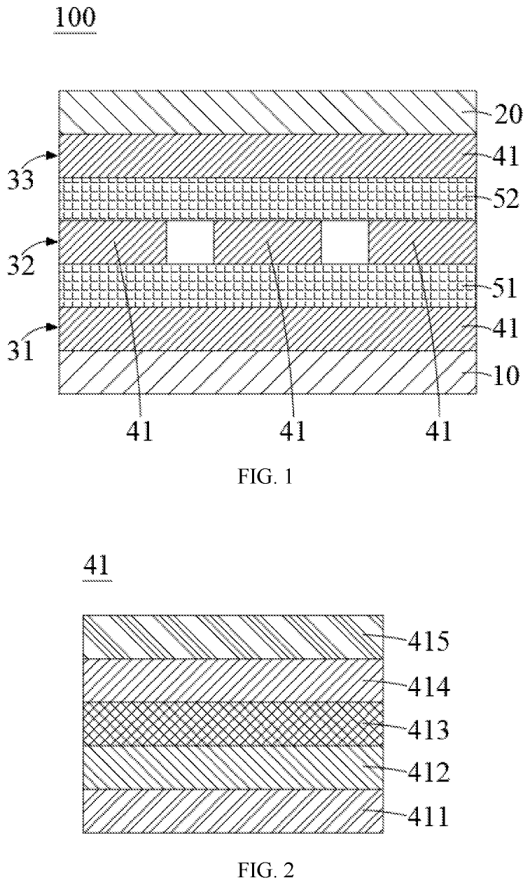

Referring to FIG. 1, FIG. 1 is a schematic diagram of an OLED display device according to a first embodiment of the present disclosure. An OLED display device 100 includes an anode 10, a cathode 20, and a plurality of OLED modules. The anode 10 and the cathode 20. The cathode 20 is correspondingly disposed to the anode 20 The plurality of OLED modules are disposed in series between the anode 10 and the cathode 20. At least one OLED module of the OLED modules includes a plurality of OLED display units 41 connected in parallel.

It should be noted that in the embodiment of the present disclosure, the term “plurality” refers to two or more, such as three, four, five, six, seven, eight, nine, ten, etc.

It should be noted that the embodiment of the present disclosure provides an OLED display device 100. The plurality of OLED modules connected in series, and at least one OLED module is provided by a plurality of OLED display units 41 connected in parallel. The plurality of OLED display units 41 connected in series or parallel are disposed between the cathode 20 and the anode 10. The OLED display device 100 can produce a larger luminous brightness under a smaller driving current, that is, under the same driving current, the luminous brightness of the OLED display device 100 is greater than the luminous brightness of the traditional OLED display device. When the luminous brightness of the OLED display device 100 is controlled to be the same as the luminous brightness of the traditional OLED display device, based on the same aging mechanism, the OLED display device 100 may obtain a longer service life than the traditional OLED display device. Due to the higher luminous brightness and longer service life, the OLED display device 100 has a wider range of applications. It is not only suitable for small-size display products such as mobile phones, but also suitable for medium-sized display products such as notebooks and tablet computers, enhancing the market competitiveness of OLED display products.

In the OLED display device 100, a plurality of OLED modules are connected in series. When the luminous efficiency of one of the OLED modules is reduced or damaged, the other OLED modules can also be operated normally, so as to ensure the normal operation of the OLED display device 100 for a long time, thereby extending the service life of the OLED display device 100. When the OLED module comprises a plurality of OLED display units 41 connected in parallel, even if the luminous efficiency of one of OLED display units 41 in the OLED module is reduced or damaged, other OLED display units 41 in the OLED module keep lighting to make OLED display device 100 normally work, thereby extending the service life of the OLED display device 100.

In some embodiments of the present disclosure, at least one of the plurality of OLED modules includes an OLED display unit 41.

For example, there are charge connection layers between any adjacent OLED modules. It is understood that the charge connection layer plays the role of connecting the various OLED modules. When an electric current is introduced, holes and electrons can also be generated in the charge connection layer and injected into the light-emitting layer 413 of the OLED module located on both sides of the charge connection layer, respectively, and electrons from the cathode 20 and holes from the anode 10 are combined in the light-emitting layer 413 to produce exciton luminescence.

It is understood that the charge connection layer needs to have light transmission performance, so that the emitted light of each OLED module can pass through the charge connection layer and then reach the light surface of the OLED display device 100. For example, for 380 nm-780 nm light, the charge connection layer has a transmittance greater than or equal to 10%, such as 10%, 20%, 30%, 40%, 50%, 60%, 70%, 80%, 90% or 100%.

In some embodiments of the present disclosure, the charge connection layer includes an N-type doping material layer and a P-type doping material layer arranged in layers. The N-type doping material layer and the P-type doping material layer are stacked to form a PN junction, and the PN junction forms an electron channel inside. When an electric field is applied, because the internal electric field of the PN junction is weaker than the applied electric field, the dipole in the PN junction will be separated to form holes and electrons. The holes and the electrons pass through the electron channel by the tunneling effect and are injected into the OLED module on both sides of the PN junction. The electrons from the cathode 20 and the hole in the anode 10 are combined in the light-emitting layer 413 of the OLED module to produce exciton luminescence.

In some embodiments, the N-type doping material layer and the P-type doping material layer are disposed sequentially in the direction from the cathode 20 to the anode 10.

In some embodiments, N-type doping material layer includes an N-type dopant and a first host material which is an organic material or an inorganic material.

In some embodiments, the P-type doping material includes a P-type dopant and a second host material which is an organic material or an inorganic material.

In some embodiments, the first host material is the same as the material of the electron transport layer 414, or the first host material is the same as the material of the electron injection layer 415. The second host material is the same as the material of the hole transport layer 412, or the material of the second host material is the same as the material of the hole injection layer 411.

Exemplary, the P-type dopant include at least one of TCNQ (7,7,8,8-tetracyanoquinone dimethane), WO₃ (tungsten trioxide), ReO₃ (rhenium trioxide) and MoO₃ (molybdenum trioxide).

Exemplary, the N-type dopant include at least one of Li (lithium), Cs (cesium), Yb (ytterbium), Cs₂CO₃ (cesium carbonate), Li₂CO₃ (lithium carbonate), Li₃N (lithium nitride).

When the OLED module comprises a plurality of OLED display units 41 connected in parallel, each of OLED display units 41 is controlled by independent switches. It is understood that during the use of the OLED display device 100, the number of operating light-emitting OLED display units 41 can be controlled by the switches to adjust the luminous brightness of the OLED display device 100. When the luminous efficiency of one of the plurality of OLED display units 41 connected in parallel is reduced or damaged, the other OLED display units 41 can be controlled to make up for the problem of reducing the luminous brightness of the OLED display device 100. In addition, adjacent two OLED display units 41 of the OLED display units connected in parallel can be alternately illuminated to ultimately extend the service life of each OLED display unit 41, thereby extending the service life of the entire OLED display device 100.

When a current flows through the anode 10 and the cathode 20 of the OLED display device 100, and the switch turns on, the OLED display unit 41 is in a power-on state. At this time, the OLED display unit 41 can emit light under the action of current. When a current flows through the anode 10 and the cathode 20 of the OLED display device 100, and the switch turns off, the OLED display unit 41 is in the unpowered state, and the OLED display unit 41 can not emit light.

The switch could be a thin-film transistor (TFT) which includes a source, a drain and a gate. When a positive voltage greater than its threshold voltage is applied to the gate, the thin-film transistor turns on. At this time, the source and drain are conducted. When the voltage applied on the gate is less than the threshold voltage, the thin-film transistor turns off. At this time, the source and the drain are not conducted. That is, the gate voltage can be used to realize the control of the switching of the thin-film transistor, and then realize the control of the OLED display unit 41 on or not.

When a thin-film transistor is used as the switch, one of the source and drain of the thin-film transistor may be connected to the OLED display unit 41, and the other of the source and drain of may be connected to the adjacent charge connection layer, the cathode 20 or the anode 10.

Referring to FIG. 2, FIG. 2 is a schematic diagram of an OLED display unit according to an embodiment of the present disclosure. The OLED display unit 41 may include a hole injection layer 411, a hole transport layer 412, a light-emitting layer 413, an electron transport layer 414 and an electron injection layer 415 stacked sequentially arranged in the direction from the anode 10 to the cathode 20.

Referring to FIG. 1, a plurality of OLED modules may include a first OLED module 31, a second OLED module 32, and a third OLED module 33 disposed sequentially in the direction from the anode 10 to the cathode 20.

Please refers to FIG. 1 and FIG. 2, each of the first OLED module 31 and the third OLED module 33 is a single OLED display unit 41.

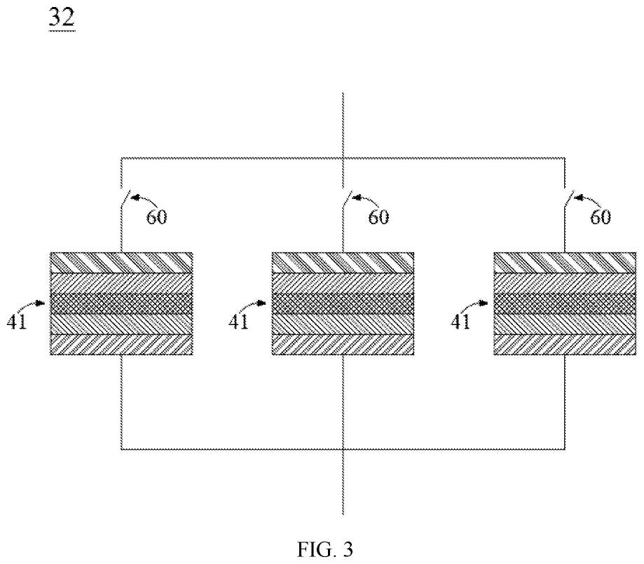

Referring to FIG. 2 and FIG. 3 illustrating a schematic diagram of the structure of an OLED module according to an embodiment of the present disclosure, the second OLED module 32 comprises a plurality of OLED display units 41 connected in parallel. Each of the OLED display units 41 is powered on or not controlled by the independent switch 60.

Referring to FIG. 1, a first charge connection layer 51 is provided between the first OLED module 31 and the second OLED module 32, a second charge connection layer 52 is provided between the second OLED module 32 and the third OLED module 33. The first charge connection layer 51 and the second charge connection layer 52 may be a charge connection layer in any of the above embodiments. Both of the first charge connection layer 51 and the second charge connection layer 52 may include an N-type doping material layer and a P-type doping material layer arranged in layers.

In conjunction with FIGS. 1 and FIG. 3, the switch 60 in the second OLED module 32 may be disposed between the first charge connection layer 51 and the OLED display unit 41 controlled by the thin-film transistor, or between the second charge connection layer 52 and the OLED display unit 41 controlled by the thin-film transistor.

When the switch 60 in the second OLED module 32 is a thin-film transistor, one of the source and drain of the thin-film transistor may be connected to the OLED display unit 41, and the other of the source and drain may be connected to the first charge connection layer 51 or the second charge connection layer 52.

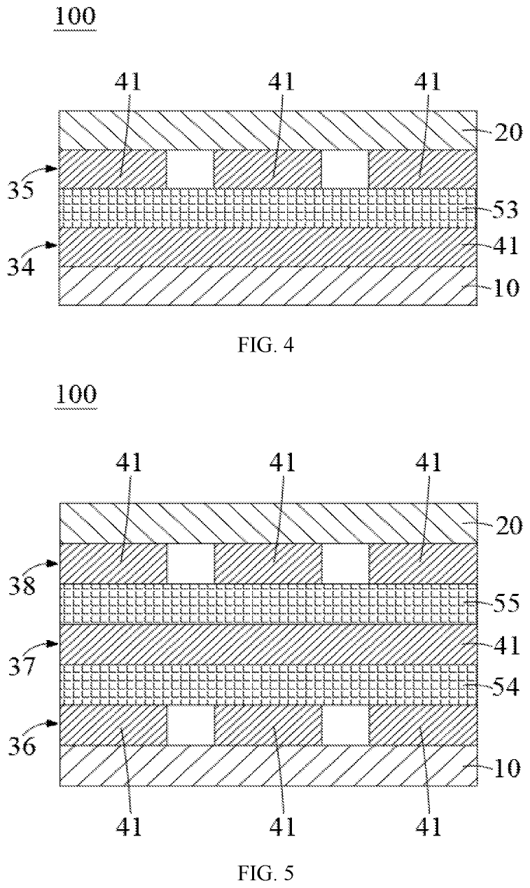

Referring to FIG. 4 illustrating a schematic diagram of an OLED display device according to a second embodiment of the present disclosure, the plurality of OLED modules include a fourth OLED module 34 and a fifth OLED module 35 disposed from the anode 10 to the cathode 20. The fourth OLED module 34 is a single OLED display unit 41, and the fifth OLED module 35 comprises the plurality of OLED display units 41 connected in parallel. As illustrated in FIG. 2, the structure of the OLED display unit 41 is shown. As illustrated in FIG. 3, the structures of the fifth OLED module 35 and the second OLED module 32 are the same. Each of the fifth OLED module 35 and the second OLED module 32 comprises the plurality of OLED display units 41 connected in parallel. In the plurality of OLED display units 41 connected in parallel, each OLED display unit 41 is controlled by an independent switch 60. In some other embodiments, the fourth OLED module 34 may comprise the plurality of OLED display units 41 connected in parallel, and the fifth OLED module 35 is a single OLED display unit 41.

Referring to FIG. 4, a third charge connection layer 53 is provided between the fourth OLED module 34 and the fifth OLED module 35. The third charge connection layer 53 may be a charge connection layer in any of the above embodiments. The third charge connection layer 53 includes an N-type doping material layer and a P-type doping material layer disposed in layers.

In conjunction with FIGS. 3 and 4, the switch 60 in the fifth OLED module 35 may be disposed between the OLED display unit 41 and the cathode 20 controlled by the thin-film transistor, or between the third charge connection layer 53 and the OLED display unit 41 controlled by the thin-film transistor.

When the switch 60 in the fifth OLED module 35 is a thin-film transistor, one of the source and drain of the thin-film transistor may be connected to the OLED display unit 41 controlled by the thin-film transistor, and the other of the source and drain may be connected to the cathode 20 or the third charge connection layer 53.

Referring to FIG. 5, FIG. 5 is a schematic diagram of an OLED display device according to a third embodiment of the present disclosure. The plurality of OLED modules include a sixth OLED module 36, a seventh OLED module 37 and an eighth OLED module 38 disposed sequentially from the anode 10 to the cathode 20. Each of the sixth OLED module 36 and the eighth OLED module 38 comprise the plurality of OLED display units 41 connected in parallel, and the seventh OLED module 37 is an OLED display unit 41. As illustrated in FIG. 2, the structure of the OLED display unit 41 is shown. As illustrated in FIG. 3, the sixth OLED module 36, the eighth OLED module 38 and the second OLED module 32 have the same structure which comprise the plurality of OLED display units 41 connected in parallel. Each OLED display unit 41 is controlled by the independent switch 60.

Referring to FIG. 5, a fourth charge connection layer 54 is provided between the sixth OLED module 36 and the seventh OLED module 37, and a fifth charge connection layer 55 is provided between the seventh OLED module 37 and the eighth OLED module 38. Each of the fourth charge connection layer 54 and the fifth charge connection layer 55 may be a charge connection layer in any of the above embodiments. The fourth charge connection layer 54 and the fifth charge connection layer 55 may include an N-type doping material layer and a P-type doping material layer disposed in layers.

In conjunction with FIGS. 3 and 5, the switch 60 in the sixth OLED module 36 may be disposed between the anode 10 and the OLED display unit 41 controlled by the thin-film transistor, or between the fourth charge connection layer 54 and the OLED display unit 41 controlled by the thin-film transistor. When the switch 60 in the sixth OLED module 36 is a thin-film transistor, one of the source and drain of the thin-film transistor may be connected to the OLED display unit 41 controlled by the thin-film transistor, and the other of the source and drain may be connected to the anode 10 or the fourth charge connection layer 54.

In conjunction with FIGS. 3 and 4, the switch 60 in the eighth OLED module 38 may be disposed between the cathode 20 and the OLED display unit 41 controlled by the thin-film transistor, or between the fifth charge connection layer 55 and the OLED display unit 41 controlled by the thin-film transistor. When the switch 60 in the eighth OLED module 38 is a thin-film transistor, one of the source and drain of the thin-film transistor may be connected to the OLED display unit 41 controlled by the thin-film transistor, and the other of the source and drain may be connected to the cathode 20 or the fifth charge connection layer 55.

In some embodiments, the anode 10 may be a transmission electrode. For 380 nm-780 nm light, the charge connection layer has a transmittance greater than or equal to 10%, such as 10%, 20%, 30%, 40%, 50%, 60%, 70%, 80%, 90% or 100%. The material of the anode 10 may include a transparent conductive metal oxide, such as indium tin oxide (ITO).

In some embodiments, the cathode 20 may be a reflective electrode. The reflectivity of the cathode 20 to 380 nm-780 nm light is greater than or equal to 10%, such as 10%, 20%, 30%, 40%, 50%, 60%, 70%, 80%, 90% or 100%. Exemplary, the material of the cathode 20 includes a metal, such as silver (Ag).

In some other embodiments, the anode 10 may be a reflective electrode, and the cathode 20 may be a transmission electrode.

It should be noted that the OLED display device 100 provided by embodiments of the present disclosure may light under a small driving current, and the luminous efficiency can increase exponentially with the number of OLED display units 41 connected in series and in parallel, so that the OLED display device 100 achieves high luminous efficiency and luminous brightness, and prolongs the service life of the OLED display device 100. Since the luminous efficiency of one of the OLED display units 41 in series and parallel is reduced or damaged will not affect the luminous stability of the entire OLED display device 100, the OLED display device 100 has good working stability. In addition, due to the low power consumption of the OLED display device 100, when the OLED display device 100 is used in electronic devices (such as mobile phones, laptops, tablet computer, etc.), a relative low volume battery may be used in the electronic device. Because a thickness of the relative low volume battery can be reduced, the electronic device can be compact. In addition, because the OLED display device 100 has a high luminous brightness, the OLED display device 100 is also suitable for the lighting field and can be applied to lighting equipment.

The above provides an OLED display device provided by an embodiment of the present disclosure in detail. Specific examples are applied herein to describe the principles and embodiments of the present disclosure, and the above embodiments are only used to help understand the present disclosure. At the same time, for those skilled in the art, according to the idea of the present disclosure, there will be changes in the specific embodiment and the scope of application, in summary, the content of this specification should not be understood as a restriction on the present disclosure.

What is claimed is:

1. An Organic Light Emitting Diode (OLED) display device, comprising:
an anode;
a cathode, correspondingly disposed to the anode; and
a plurality of OLED modules, disposed in series between the anode and the cathode, wherein one of the plurality of OLED modules includes a plurality of OLED display units connected in parallel.

2. The OLED display device according to claim 1, wherein the plurality of OLED display units connected in parallel are controlled individually by independent switches.

3. The OLED display device according to claim 1, wherein at least one of the plurality of OLED modules is a single OLED display unit.

4. The OLED display device according to claim 1, wherein the OLED display unit includes a hole injection layer, a hole transport layer, a light-emitting layer, an electron transport layer, and an electron injection layer laminated in succession in a direction from the anode to the cathode.

5. The OLED display device according to claim 1, wherein there is a charge connection layer disposed between any two adjacent OLED modules of the plurality of OLED modules.

6. The OLED display device according to claim 5, wherein the charge connection layer includes an N-type doping material layer and a P-type doping material layer disposed in layers.

7. The OLED display device according to claim 6, wherein the N-type doping material layer includes an N-type dopant and a first host material that is an organic material, and the P-type doping material layer includes a P-type dopant and a second host material that is an organic material.

8. The OLED display device according to claim 7, wherein the first host material and a material of the electron transport layer are identical, or the first host material and a material of the electron injection layer are identical;
the second host material and a material of the hole transport layer are identical, or the second host material and a material of the hole injection layer are identical.

9. The OLED display device according to claim 7, wherein the P-type dopant is selected from TCNQ, WO₃, ReO₃ and MoO₃, and the N-type dopant is selected from Li, Cs, Yb, Cs₂CO₃, Li₂CO₃, and Li₃N.

10. The OLED display device according to claim 1, wherein the plurality of OLED modules include a first OLED module, a second OLED module, and a third OLED module set sequentially in a direction from the anode to the cathode; the OLED display device further includes a first charge connection layer connected between the first OLED module and the second OLED module, and a second charge connection layer connected between the second OLED module and the third OLED module; each of the first OLED module and the third OLED module is composed of a single OLED display unit, and the second OLED module is composed of a plurality of OLED display units connected in parallel.

11. The OLED display device according to claim 1, wherein the plurality of OLED modules include a fourth OLED module and a fifth OLED module disposed sequentially in a direction from the anode to the cathode; the OLED display device further includes a third charge connection layer provided between the fourth OLED module and the fifth OLED module;
wherein the fourth OLED module is composed of a single OLED display unit, and the fifth OLED module is composed of a plurality of OLED display units connected in parallel.

12. The OLED display device according to claim 1, wherein the plurality of OLED modules include a sixth OLED module, a seventh OLED module, and an eighth OLED module disposed sequentially in the direction from the anode to the cathode; the OLED display device further includes a fourth charge connection layer connected between the sixth OLED module and the seventh OLED module, and a fifth charge connection layer connected between the seventh OLED module and the eighth OLED module; each of sixth OLED module and the eighth OLED module is composed of a plurality of OLED display units connected in parallel, and the seventh OLED module is composed of a single OLED display unit.

13. An Organic light emitting diode (OLED) display device, comprising:
an anode;
a cathode; and
a plurality of OLED modules, disposed between the anode and the cathode, wherein one of the plurality of OLED modules includes a plurality of OLED display units connected in parallel, and the plurality of OLED display units are controlled individually to adjust a luminous brightness of the OLED display device.

14. The OLED display device according to claim 13, wherein the plurality of OLED display units connected in parallel are controlled individually by independent switches.

15. The OLED display device according to claim 13, wherein at least one of the plurality of OLED modules is composed of a OLED display unit.

16. The OLED display device according to claim 13, wherein the OLED display unit includes a hole injection layer, a hole transport layer, a light-emitting layer, an electron transport layer, and an electron injection layer laminated in succession in a direction from the anode to the cathode.

17. The OLED display device according to claim 16, wherein there is a charge connection layer disposed between any two adjacent OLED modules of the plurality of OLED modules.

18. The OLED display device according to claim 17, wherein the charge connection layer includes an N-type doping material layer and a P-type doping material layer disposed in layers.

19. The OLED display device according to claim 18, wherein the N-type doping material layer includes an N-type dopant and a first host material that is an organic material, and the P-type doping material layer includes a P-type dopant and a second host material that is an organic material.

20. The OLED display device according to claim 19, wherein the first host material and a material of the electron transport layer are identical, or the first host material and a material of the electron injection layer are identical;
the second host material and a material of the hole transport layer are identical, or the second host material and a material of the hole injection layer are identical.
